(19) United States
(12) Patent Application Publication
(10) Pub. No.: US 2015/0155397 A1
(43) Pub. Date: Jun. 4, 2015

(54) FILTER SYSTEM FOR PHOTOACTIVE COMPONENTS

(71) Applicant: HELIATEK GMBH, Dresden (DE)

(72) Inventors: Karsten Walzer, Dresden (DE); Bert Maennig, Dresden (DE)

(73) Assignee: HELIATEK GMBH, Dresden (DE)

(21) Appl. No.: 14/406,457

(22) PCT Filed: Jun. 5, 2013
(86) PCT No.: PCT/IB2013/054625

§ 371 Date: Dec. 8, 2014

(30) Foreign Application Priority Data
Jun. 11, 2012 (DE) 102012105013.9

(51) Int. Cl. H01L 31/0216; H02S 40/20

(52) U.S. Cl. CPC H01L 31/02162; H02S 40/20

(57) ABSTRACT

A photoactive component on a substrate includes a first and a second electrode. The first electrode is arranged on the substrate and the second electrode forms a counterelectrode. At least one photoactive layer system is arranged between the electrodes. The photoactive component furthermore includes at least one layer or layer sequence configured such that the layer or layer sequence acts as a spectrally selective color filter in the range from 450 nm to 800 nm in the photoactive component.

The invention relates to a filter system for photoactive components.

Photoactive components, such as solar cells, for instance, currently find broad application in the everyday and industrial sphere. There is particular interest here in the integration of photovoltaic elements in buildings (GiPV [abbreviation of German gebäudeintegrierte Photovoltaik], often also referred to as BiPV from English: Building-integrated Photovoltaics) or in vehicles (AiPV), wherein not only traditional energy generation (conversion of sunlight into electricity) but also further functions are desired. The expert group “Photovoltaics in buildings” under the auspices of the German Federal Association for Construction Systems [Bundesverband für Bausysteme e. V.] describes BiPV as architectural, construction-physical and structural incorporation of PV elements into the building envelope taking account of the multifunctional properties of the PV module.

Especially the integration of photoactive components in glass elements is of particular interest, this being applicable not only to the BiPV field, but also to other fields, such as the automotive field, for instance.

Integration in glass facades presents certain difficulties, however, since a color-neutral impression is often desired. This is difficult to realize, however, especially in the case of colored absorber systems.

In addition, there is also the requirement to permit the transmission only of specific wavelength ranges by the photoactive component. As a result, by way of example, specific wavelength ranges can selectively pass through the photoactive component, this being desirable for example in the field of plant cultivation, for instance in the case of use in greenhouses.

Specific fields of use of solar cells possibly require adaptation of the visual appearance, especially of the color impression.

This may be desired both for opaque and for semitransparent solar cells.

Various aims may be established in this context, e.g. achieving a specific object color or achieving a specific color for transmitted light.

The object color is relevant e.g. in the case of design or BiPV applications in which the customer would like to choose the color of their product or their building envelope, or in the case of tinted motor vehicle panes, where a different color nuance is desired depending on the manufacturer.

The color of transmitted light may be relevant e.g. if color neutrality of the transmitted light is intended to be achieved, i.e. if the solar cell through which light is to pass is intended to act substantially as a neutral filter for reducing the incidence of light. This may be the case e.g. in BiPV solutions in which as viewed spectrally, daylight conditions are intended to prevail in the interior of a building.

A similar application arises in motor vehicles in which, depending on the manufacturer and purpose of use, differently tinted vehicle panes provided with semitransparent photovoltaics are intended to be used.

Previous solutions are characterized by the use of silicon-based solar modules, which are usually embodied in panel form. In this context, arrangement on building surfaces is usually implemented by means of support systems on roofs or curtain systems on walls. Such systems are characterized in particular by their structurally complex construction and by the overall high weight. Moreover, the structures for accommodating corresponding panel-type modules must afford adequate safeguarding of the modules against falling down, since the panel-type modules—on account of their inherent weight—otherwise constitute corresponding risks for persons and objects.

What is problematic, moreover, is that silicon-based modules—for an optimum efficiency—require an alignment to the south and possibly an installation angle of 30° in order to ensure optimum insolation.

An additional factor is that silicon-based photovoltaic modules have power losses as a result of an elevated temperature that forms in the modules owing to direct solar irradiation. Therefore, it is advantageous to use corresponding systems with active or passive rear ventilation.

A direct arrangement of silicon-based cells on building surfaces is difficult against the background of the above-described alignment to the south, the necessary installation angle, safeguarding against dropping down and background ventilation.

Alternative systems provide photovoltaic elements integrated directly in roof tiles, for example.

Arched or curved building surfaces, for instance of glass facades, have presented particular challenges hitherto. In this context, corresponding geometries can be realized only with difficulty when silicon-based panel-type modules are used.

Thin-film solar cells with a flexible configuration are appropriate, for instance, as an alternative to panel-type modules.

In this regard, thin-film solar cells are known, for example, which have a flexible configuration and thus allow arrangement on curved surfaces. In this context, such solar cells preferably comprise active layers composed of amorphous or non-crystalline silicon (α-Si, μ-Si), CdTe or CIGS (Cu(In,Ga)(S,Se)₂).

What is disadvantageous about said thin-film solar cells is the production costs, which are still high owing to the materials.

Solar cells comprising organic active layers which are configured flexibly (Konarka-Power Plastic Series) are well known as well. In this context, the organic active layers can be constructed from polymers (e.g. U.S. Pat. No. 7,825,326 B2) or small molecules (e.g. EP 2385556 A1). While polymers are distinguished by the fact that they cannot be evaporated and can therefore be applied only from solutions, small molecules are evaporable.

The advantage of such components on an organic basis compared with the conventional components on an inorganic basis (semiconductors such as silicon, gallium arsenide) is the in some instances extremely high optical absorption coefficients (up to 2×10⁵ cm⁻¹), thus affording the possibility of producing very thin solar cells with low material and energy outlay. Further technological aspects include the low costs, the possibility of producing flexible large-area construction parts on plastic films, and the virtually unlimited variation possibilities and the unlimited availability of organic chemistry. A further advantage resides in the possibility of being able to produce transparent components which can be used in glass applications, for example. A further major advantage is the lower costs compared with inorganic semiconductor components.

A solar cell converts light energy into electrical energy. In this case, the term photoactive likewise denotes the conversion of light energy into electrical energy. In contrast to inorganic solar cells, in organic solar cells the light does not directly generate free charge carriers, rather excitons initially form, that is to say electrically neutral excitation states (bound electron-hole pairs). It is only in a second step that these excitons are separated into free charge carriers which then contribute to the electric current flow.

One possibility for the realization of an organic solar cell that has already been proposed in the literature consists in a pin diode [Martin Pfeiffer, “Controlled doping of organic vacuum deposited dye layers: basics and applications”, PhD thesis TU-Dresden, 1999] having the following layer construction:

0. carrier, substrate,
1. bottom contact, normally transparent,
2. p-layer(s),
3. i-layer(s),
4. n-layer(s),
5. top contact.

In this case, n and p denote an n-type and p-type doping, respectively, which lead to an increase in the density of free electrons and holes, respectively, in the thermal equilibrium state. However, it is also possible for the n-layer(s) and p-layer(s) to be at least partly nominally undoped and to have preferably n-conducting and preferably p-conducting properties, respectively, only on account of the material properties (e.g. different mobilities), on account of unknown impurities (e.g. residual residues from the synthesis, decomposition or reaction products during the layer production) or on account of influences of the surroundings (e.g. adjacent layers, indiffusion of metals or other organic materials, gas doping from the surrounding atmosphere). In this sense, layers of this type should primarily be understood as transport layers. By contrast, the designation i-layer denotes a nominally undoped layer (intrinsic layer). In this case, one or a plurality of i-layers can consist layers either composed of one material, or a mixture composed of two materials (so-called interpenetrating networks or bulk heterojunction; M. Hiramoto et al. Mol. Cryst. Liq. Cryst., 2006, 444, pp. 33-40). The light incident through the transparent bottom contact generates excitons (bound electron-hole pairs) in the i-layer or in the n-/p-layer. Said excitons can only be separated by very high electric fields or at suitable interfaces. Sufficiently high fields are not available in organic solar cells, with the result that all promising concepts for organic solar cells are based on the separation of excitons at photoactive interfaces. The excitons pass by diffusion to such an active interface, where electrons and holes are separated from one another. In this case, the material which takes up the electrons is designated as acceptor, and the material which takes up the hole is designated as donor. The separating interface can lie between the p- (n-) layer and the i-layer or between two i-layers. In the built-up electric field of the solar cell, the electrons are then transported away to the n-region and the holes to the p-region. Preferably, the transport layers are transparent or largely transparent materials having a large band gap (wide-gap) such as are described e.g. in WO 2004083958. In this case, the term wide-gap materials denotes materials whose absorption maximum lies in the wavelength range of <450 nm, and is preferably <400 nm.

Since the light always generates excitons first, and does not yet generate free charge carriers, the diffusion of excitons to the active interface with little recombination plays a critical part in organic solar cells. In order to make a contribution to the photocurrent, it is necessary, therefore, in a good organic solar cell, for the exciton diffusion length to distinctly exceed the typical penetration depth of the light, in order that the predominant part of the light can be utilized. Organic crystals or thin layers that are perfect structurally and with regard to chemical purity do indeed fulfil this criterion. For large-area applications, however, the use of monocrystalline organic materials is not possible and the production of multilayers with sufficient structural perfection is still very difficult to date.

Systems for integrating solar cells in buildings are known, wherein flexible solar cells are also used. In this regard, JP 2011-109051A discloses the arrangement of an amorphous solar cell on a plastic panel, which can subsequently be fitted to buildings. On account of the configuration, however, sufficient flexibility of the module thus fashioned, which flexibility would require arrangement on curved and arched surfaces, cannot be expected.

EP 1191605 A2 describes a glassless, flexible solar laminate for use in building technology, wherein the solar cells are applied to a steel plate under pressure and temperature (approximately 130° C.) and subsequently fitted on building exterior surfaces by means of an adhesive layer arranged at the rear side.

WO20120303971 describes a flexible thin-film solar cell module on the basis of CIGS (Copper indium gallium diselenide) comprising a plurality of layers of thin-film solar cells joined together by means of lamination. At its rear side the module has an adhesive layer for arrangement on building exterior surfaces.

The demand for increasing integration of solar modules in buildings and structures even with complex geometry requires new concepts for fashioning the solar modules and arranging the solar modules on shaped parts.

The object of the present invention therefore consists in specifying a solar module which overcomes the disadvantages of the prior art.

The object is achieved by means of a component according to the main claim. Advantageous configurations are specified in the dependent claims.

The invention proposes a photoactive component on a substrate comprising a first and a second electrode wherein the first electrode is arranged on the substrate and the second electrode forms a counterelectrode, wherein at least one photoactive layer system is arranged between said electrodes. According to the invention, the photoactive component furthermore comprises at least one layer or layer sequence configured such that said layer or layer sequence acts as a spectrally selective color filter in the VIS range in the photoactive component. In this case, spectrally selective color filter means that the layer or layer sequence acting as a color filter absorbs in a specific wavelength range of the visible spectrum in the range from 450 nm to 800 nm, wherein the color filter is selected in accordance with the application requirements. Both the transmission and the reflection of the photoactive component can be set by means of the selection of the spectrally selective color filter.

In a further embodiment of the invention, the photoactive component furthermore comprises at least one layer or layer sequence configured such that the latter acts as a spectrally selective IR filter in the IR range in the photoactive component. In this case, spectrally selective IR filter means that the layer or layer sequence acting as an IR filter absorbs in a specific wavelength range of the IR spectrum in the range from 1100 nm to 2500 nm, wherein the IR filter is selected in accordance with the application requirements. The additional IR filter reduces the input of thermal energy, for example into buildings. High heating in buildings or greenhouses can be avoided as a result. Likewise, excessively high heating of the solar cell, which in the case of solar cells having a negative temperature coefficient leads to reduction of the yield as the temperature increases, is thus prevented.

In a further embodiment of the invention, the photoactive component furthermore comprises at least one layer or layer sequence configured such that the latter acts as a spectrally selective UV filter in the UV range from 250 nm to 430 nm in the photoactive component. The additional UV filter protects for example the organic molecules contained in the photoactive component against possible degradation. The same applies to polymers, adhesives and laminating substances possibly used.

In a first embodiment, the layer or layer sequence acting as a color filter comprises at least one absorbent material, wherein the layer is configured such that it has no electrical contact-connection.

In a further embodiment of the invention, the layer or layer sequence acting as a color filter is arranged outside the electrically active part of the photoactive component, i.e. outside the electrodes.

In a further embodiment of the invention, the layer or layer sequence acting as a color filter comprises organic and/or inorganic substances or a combination thereof. Organic dyes are preferably used. Said organic dyes have a spectral full width at half maximum of typically between 50 nm and 300 nm and are particularly suitable for selective filtering in the visible range on account of this selectivity.

In a further embodiment of the invention, the layer or layer sequence acting as a color filter comprises nanomaterials, such as, for instance, nanocrystals, nanowires, nanoparticles, embodied as a color-selectively absorbent layer.

In a further embodiment of the invention, the layer or layer sequence acting as a color filter is arranged either on the side of the photoactive component facing the light incidence or on the side of the photoactive component facing away from the light incidence.

In one configuration of this embodiment, the layer or layer sequence acting as a color filter is arranged on the side of the photoactive component facing the light incidence, wherein the layer or layer sequence is configured such that it transmits that part of the spectrum which is relevant for the effect of the photoactive component.

In a further embodiment of the invention, the layer or layer sequence acting as a color filter comprises at least one fluorescent dye. Said fluorescent dye can be chosen such that it absorbs light from a selected spectral range and emits light in a desired spectral range. As a result, the color impression can be adapted, for example. On account of the emission by the fluorescent dye, this can result in reabsorption in the photoactive layer system of the photoactive component and thus an increase in efficiency. Given a corresponding selection of the fluorescence emitter in accordance with the user's requirements surfaces fashioned in a colored manner can be implemented. This is of interest for advertising applications, for example.

In one embodiment of the invention, the layer or layer sequence acting as a color filter on the light-facing side of the photoactive component is embodied as a metallic structure, such as, for instance, metal layer, metal grating, etc. The metallic structure advantageously has a layer thickness of between 1 and 10 nm.

In one configuration of the embodiment, the layer or layer sequence acting as a color filter is arranged on the side of the photoactive component facing away from the light incidence. This solution is advantageous whenever the layer or layer sequence acting as a color filter absorbs no light which can also be used by the photoactive layer of the photoactive component. This is achieved without losses by virtue of the fact that the layer or layer sequence acting as a color filter comprises an additional absorber, which is applied on the side facing away from the light incidence, or by the choice of a selective absorber which filters out the entering light in undesirable spectral ranges and can act e.g. as a UV filter. Components configured in this way can be used particularly advantageously for example where only specific wavelength ranges are intended to pass through the photoactive component. This is conceivable for example in the case of integration in glass or application of the components on films. Components configured in this way are particularly suitable for example for arrangement on greenhouses. In this context, by way of example, filtering can be realized to the effect that radiation in the infrared range cannot pass through, as a result of which heating within the greenhouse can be avoided. This is realized for example by means of a plurality of layers composed of metal or metal oxide. At the same time, the layer acting as a color filter is configured such that the spectral ranges necessary for the plants can pass through. As a result, besides the generation of electricity by means of the photoactive component enough light to ensure optimum growth of the plants can also pass through. In this case, the electricity generated by the photoactive component can be used for example to operate an additional illumination or ventilation, which, with a decreasing amount of light, is used to lengthen the illumination phase or to operate sprinkler systems. The resultant infrared filtering additionally prevents heating within the greenhouse. The configuration is also advantageous to the effect that the photoactive component is arranged on a transparent or opaque flexible substrate, as a result of which the greenhouse can be erected directly from the components arranged on the substrate. Greenhouses of lightweight design can arise as a result.

In a further embodiment of the invention, the layer or layer sequence acting as a color filter is embodied as a thin-film layer applied in vacuo or from solution. In one configuration of the above-described embodiment, the layer or layer sequence has a layer thickness of at least 3 nm to 100 μm, preferably between 5 nm and 300 nm.

In a further embodiment of the invention, the layer or layer sequence acting as a color filter comprises at least one absorber. In one configuration of the above-described embodiment, the layer or layer sequence acting as a color filter comprises a mixture and/or sequence of two or more absorbers. The case where more than one additional absorber is used has the advantage that a further spectral widening thus becomes possible, which is advantageous, e.g. for achieving color neutrality.

In a further embodiment of the invention, the layer or layer sequence acting as a color filter is embodied as a film colored with organic or inorganic dyes. In one configuration of this embodiment, the film has a thickness of at least 3 μm to 1000 μm, preferably 10 μm to 300 μm.

In a further embodiment of the invention, the layer or layer sequence acting as a color filter is embodied as a glass colored with organic or inorganic dyes, having a thickness of at least 50 μm.

In one alternative embodiment of the invention, the layer or layer sequence acting as a color filter is embodied as a charge carrier transport layer having absorption in at least one subrange of the wavelength range. In this case, the at least one charge carrier transport layer functions as a color filter. In this case, the charge carrier transport layer comprises at least one hole conductor (HTL) and/or electron conductor material (ETL) chosen such that these have selective absorption in the desired wavelength range and thus set the color appearance.

This can be implemented by virtue of the fact that either the ETL/HTL materials themselves are colored or they contain an admixture which is absorbent selectively in a colored manner. In this case, the light absorbed in these charge carrier transport layers does not contribute to the generation of charge carriers, which differentiates this charge carrier transport layer from the absorbers in the photoactive layer.

By virtue of the targeted selection of the materials for the charge carrier transport layers, a color filter integrated in the photoactive component can thus be realized without an additional layer having to be arranged outside the electrodes.

In a further embodiment of the invention, the layer or layer sequence acting as a color filter is used to compensate for inhomogeneities in the color impression. This may be the case with production-dictated different layer thicknesses, for example, where the layers of the photoactive component are deposited to a lesser extent in the edge region, for instance.

In a further embodiment of the invention, the layer or layer sequence acting as a color filter has a structuring. As a result, inhomogeneities in the color impression of the photoactive component are deliberately generated, which leads to the perception of a pattern. As a result, by way of example, logos etc. can be realized in order to realize an individualization of the component in accordance with the user's requirements.

In one embodiment of the invention, the substrate is embodied as opaque or transparent.

In one embodiment of the invention, the layer or layer sequence acting as a color filter has a layer thickness of between 5 and 500 nm, as a result of which an adaptation of the filter effect is obtained by means of thin-film-optical effects.

In one embodiment of the invention, the substrate is embodied as glass or film.

In one embodiment of the invention, at least one organic layer composed of at least one organic material is used in the photoactive component, said at least one organic layer being arranged between the electrode and the counterelectrode.

In one embodiment of the invention, the organic layer is embodied as an active layer in the photoactive component.

In a further embodiment of the invention, the active layer comprises at least one organic material.

In a further embodiment of the invention, the active layer comprises at least one mixed layer comprising at least two main materials, wherein the latter form an active donor-acceptor system.

In a further embodiment of the invention, at least one main material is an organic material.

In a further embodiment of the invention, the organic material comprises small molecules. Within the meaning of the invention, the term small molecules is understood to mean monomers which can be evaporated in vacuo and thus deposited on the substrate.

In a further embodiment of the invention, the organic material at least partly comprises polymers. In this case, however, at least one photoactive i-layer is formed from small molecules.

In a further embodiment of the invention, at least one of the active mixed layers comprises a material from the group of fullerenes or fullerene derivatives as acceptor.

In a further embodiment of the invention, at least one doped, partly doped or undoped transport layer is arranged between the electrode and the counter electrode.

In a further embodiment of the invention, the component is semitransparent at least in a certain light wavelength range between 200 nm and 3 μm.

In a further embodiment of the invention, the photoactive component is an organic solar cell.

In a further embodiment of the invention, the component is a pin individual, pin tandem cell, pin multiple cell, nip individual cell, nip tandem cell or nip multiple cell.

In a further embodiment of the invention, the component consists of a combination of nip, ni, ip, pnip, pni, pip, nipn, nin, ipn, pnipn, pnin or pipn structures in which a plurality of independent combinations containing at least one i-layer are stacked one above another.

In a further embodiment of the invention, the photoactive component comprises more than one photoactive layer between the electrode and the counterelectrode.

In a further embodiment of the invention, the active layer system of the photoactive component consists at least of two mixed layers which directly adjoin one another, and at least one of the two main materials of one mixed layer is a different organic material than the two main materials of another mixed layer. Each mixed layer consists of at least two main materials, wherein the latter form a photoactive donor-acceptor system. The donor-acceptor system is distinguished by the fact that at least for the photo-excitation of the donor component it holds true that the excitons formed at the interface with the acceptor are preferably separated into a hole on the donor and an electron on the acceptor. The term main material denotes a material whose proportion by volume or by mass in the layer is greater than 16%. Further materials can be admixed in a manner governed by technical dictates or else for the purpose of setting layer properties. Even with a double mixed layer, the component contains three or four different absorber materials and can thus cover a spectral range of approximately 600 nm or approximately 800 nm.

In a further embodiment of the invention, the double mixed layer can also be used to obtain significantly higher photocurrents for a specific spectral range by virtue of materials being mixed which preferably absorb in the same spectral range. This can then furthermore be used to achieve current matching between the different subcells in a tandem solar cell or multiple solar cell. Therefore, a further possibility of matching the currents of the subcells is afforded besides the use of the cavity layer.

In a further embodiment of the invention, in order to improve the charge carrier transport properties of the mixed layers, the mixing ratios in the different mixed layers can be identical or else different.

In a further embodiment of the invention, the mixed layers preferably consist of two main materials in each case.

In a further embodiment of the invention, a gradient of the mixing ratio can be present in the individual mixed layers.

In one preferred configuration of the invention, the photoactive component is embodied as tandem cells and, owing to the use of double or multiple mixed layers, there is the further advantage that the current matching between the subcells can be optimized by the choice of the absorber materials in the mixed layers and the efficiency can thus be increased further.

In a further embodiment of the invention, in this case, the individual materials can be positioned in different maxima of the light distribution of the characteristic wavelengths absorbed by said material. In this regard, by way of example, one material in a mixed layer can lie in the 2^{nd} maximum of its characteristic wavelength, and the other material in the 3^{rd} maximum.

In a further embodiment of the invention, the photoactive component, in particular an organic solar cell, consists of an electrode and a counterelectrode and at least two organic active mixed layers between the electrodes, wherein the mixed layers in each case substantially consist of two materials and the two main materials of a respective mixed layer form a donor-acceptor system and the two mixed layers directly adjoin one another and at least one of the two main materials of one mixed layer is a different organic material than the two main materials of another mixed layer.

In one development of the above-described embodiment, a plurality or all of the main materials of the mixed layers differ from one another.

In a further embodiment of the invention, three or more mixed layers arranged between the electrode and counterelectrode are involved.

In a further embodiment of the invention, even further photoactive individual or mixed layers in addition to the mixed layers mentioned are present.

In a further embodiment of the invention, at least one further organic layer is also present between the mixed layer system and the one electrode.

In a further embodiment of the invention, at least one further organic layer is also present between the mixed layer system and the counterelectrode.

In a further embodiment of the invention, one or a plurality of the further organic layers are doped wide-gap layers, wherein the maximum of the absorption is at <450 nm.

In a further embodiment of the invention, at least two main materials of the mixed layers have different optical absorption spectra.

In a further embodiment of the invention, the main materials of the mixed layers have different optical absorption spectra which mutually complement one another in order to cover the widest possible spectral range.

In a further embodiment of the invention, the absorption range of at least one of the main materials of the mixed layers extends into the infrared range.

In a further embodiment of the invention, the absorption range of at least one of the main materials of the mixed layers extends into the infrared range in the wavelength range from >700 nm to 1500 nm.

In a further embodiment of the invention, the HOMO and LUMO levels of the main materials are adapted such that the system enables a maximum open-circuit voltage, a maximum short-circuit current and a maximum filling factor.

In a further embodiment of the invention, at least one of the photoactive mixed layers contain a material from the group of fullerenes or fullerene derivatives (C₆₀, C₇₀, etc.) as acceptor.

In a further embodiment of the invention, all of the photoactive mixed layers contain a material from the group of fullerenes or fullerene derivatives (C₆₀, C₇₀, etc.) as acceptor.

In a further embodiment of the invention, at least one of the photoactive mixed layers contains as donor a material from the class of phthalocyanines, perylene derivatives, TPD derivatives, oligothiophenes or a material as described in WO2006092134.

In a further embodiment of the invention, at least one of the photoactive mixed layers contains the material fullerene C₆₀ as acceptor and the material 4P-TPD as donor.

In a further embodiment of the invention, the contacts consist of metal, a conductive oxide, in particular ITO, ZnO:Al, or other TCOs, or a conductive polymer, in particular PEDOT:PSS or PANI.

Within the meaning of the invention, polymer solar cells comprising two or more photoactive mixed layers are also encompassed, wherein the mixed layers directly adjoin one another. In the case of polymer solar cells, however, there is the problem that the materials are applied from solution and, consequently, a further applied layer very easily has the effect that the underlying layers are insipiently dissolved, dissolved or altered in terms of their morphology. In the case of polymer solar cells, therefore, multiple mixed layers can be produced only to a very limited extent, and also only by the use of different material and solvent systems which do not or scarcely influence one another during production. Solar cells composed of small molecules have a very clear advantage here since arbitrary systems and layers can be applied to one another by means of the vapor deposition process in vacuo and the advantage of the multiple mixed layer structure can thus be utilized very broadly and realized with arbitrary material combinations.

A further embodiment of the component according to the invention consists in the fact that a p-doped layer is also present between the first electron-conducting layer (n-layer) and the electrode situated on the substrate, with the result that a pnip or pni structure is involved, wherein the doping is preferably chosen to be high enough that the direct pn contact has no blocking effect, rather low-loss recombination occurs, preferably by means of a tunneling process.

In a further embodiment of the invention, a p-doped layer can also be present in the component between the active layer and the electrode situated on the substrate, with the result that a pip or pi structure is involved, wherein the additional p-doped layer has a Fermi level situated at most 0.4 eV, but preferably less than 0.3 eV, below the electron transport level of the i-layer, with the result that low-loss electron extraction from the i-layer into this p-layer can occur.

In a further embodiment of the invention, an n-layer system is also present between the p-doped layer and the counterelectrode, with the result that an nipn or ipn structure is involved, wherein the doping is preferably chosen to be high enough that the direct pn contact has no blocking effect, rather low-loss recombination occurs, preferably by means of a tunneling process.

In a further embodiment, an n-layer system can also be present in the component between the intrinsic, photoactive layer and the counterelectrode, with the result that an nin or in structure is involved, wherein the additional n-doped layer has a Fermi level situated at most 0.4 eV, but preferably less than 0.3 eV, above the hole transport level of the i-layer, with the result that low-loss hole extraction from the i-layer into this n-layer can occur.

A further embodiment of the component according to the invention consists in the fact that the component contains an n-layer system and/or a p-layer system, with the result that a pnipn, pnin, pipn or p-i-n structure is involved, which in all cases are distinguished by the fact that—independently of the conduction type—the layer adjoining the photoactive i-layer on the substrate side has a lower thermal work function than the layer adjoining the i-layer and facing away from the substrate, with the result that photogenerated electrons are preferably transported away toward the substrate if no external voltage is applied to the component.

In a further embodiment of the invention, a plurality of conversion contacts are connected in series with the result that e.g. an npnipn, pnipnp, npnipnp, pnpnipnpn or pnpnpnipnpnpn structure is involved.

In one preferred development of the structures described above, the latter are embodied as an organic tandem solar cell or multiple solar cell. Thus, the component can be a tandem cell composed of a combination of nip, ni, ip, pnip, pni, pip, nipn, nin, ipn, pnipn, pnin or pipn structures, wherein a plurality of independent combinations containing at least one i-layer are stacked one above another (cross-combinations).

In a further embodiment of the structures described above, the latter is embodied as a pnipnipn tandem cell.

In a further embodiment, the acceptor material in the mixed layer is present at least partly in crystalline form.

In a further embodiment, the donor material in the mixed layer is present at least partly in crystalline form.

In a further embodiment, both the acceptor material and the donor material in the mixed layer are present at least partly in crystalline form.

In a further embodiment, the acceptor material has an absorption maximum in the wavelength range >450 nm.

In a further embodiment, the donor material has an absorption maximum in the wavelength range >450 nm.

In a further embodiment, the active layer system also contains further photoactive individual or mixed layers in addition to the mixed layer mentioned.

In a further embodiment, the n-material system consists of one or more layers.

In a further embodiment, the p-material system consists of one or more layers.

In a further embodiment, the n-material system contains one or more doped wide-gap layers. In this case, the term wide-gap layers defines layers having an absorption maximum in the wavelength range <450 nm.

In a further embodiment, the p-material system contains one or more doped wide-gap layers.

In a further embodiment, the component contains a p-doped layer between the first electron-conducting layer (n-layer) and the electrode situated on the substrate, with the result that a pnip or pni structure is involved.

In a further embodiment, the component contains a p-doped layer between the photoactive i-layer and the electrode situated on the substrate, with the result that a pip or pi structure is involved, wherein the additional p-doped layer has a Fermi level situated at most 0.4 eV, but preferably less than 0.3 eV, below the electron transport level of the i-layer.

In a further embodiment, the component contains an n-layer system between the p-doped layer and the counterelectrode, with the result that an nipn or ipn structure is involved.

In a further embodiment, the component contains an n-layer system between the photoactive i-layer and the counterelectrode, with the result that an nin or in structure is involved, wherein the additional n-doped layer has a Fermi level situated at most 0.4 eV, but preferably less than 0.3 eV, above the hole transport level of the i-layer.

In a further embodiment, the component contains an n-layer system and/or a p-layer system, with the result that a pnipn, pnin, pipn or p-i-n structure is involved.

In a further embodiment, the additional p-material system and/or the additional n-material system contains one or more doped wide-gap layers.

In a further embodiment, the component contains still further n-layer systems and/or p-layer systems, with the result that e.g. an npnipn, pnipnp, npnipnp, pnpnipnpn or pnpnpnipnpnpn structure is involved.

In a further embodiment, one or more of the further p-material systems and/or of the further n-material systems contain(s) one or more doped wide-gap layers.

In a further embodiment, the component is a tandem cell composed of a combination of nip, ni, ip, pnip, pni, pip, nipn, nin, ipn, pnipn, pnin or pipn structures.

In a further embodiment, the organic materials are at least in part polymers, but at least one photoactive i-layer is formed from small molecules.

In a further embodiment, the acceptor material is a material from the group of fullerenes or fullerene derivatives (preferably C₆₀ or C₇₀) or a PTCDI derivative (perylene-3,4,9,10-bis(dicarboximide) derivative).

In a further embodiment, the donor material is an oligomer, in particular an oligomer according to WO2006092134, a porphyrin derivative, a pentacene derivative or a perylene derivative, such as DIP (di-indeno-perylene), DBP (di-benzo-perylene).

In a further embodiment, the p-material system contains a TPD derivative (triphenylamine-dimer), a spiro compound, such as spiropyrans, spirooxazines, MeO-TPD (N,N,N′,N′-tetrakis(4-methoxyphenyl)benzidine), di-NPB (N,N′-diphenyl-N,N′-bis(N,N′-di(1-naphthyl)-N,N′-diphenyl-(1,1′-biphenyl) 4,4′-diamines)), MTDATA (4,4′,4″-tris(N-3-methylphenyl-N-phenylamino)triphenylamine), TNATA (4,4′,4″-tris[N-(1-naphthyl)-N-phenylamino]triphenylamine), BPAPF (9,9-bis {4-[di-(p-biphenyl)aminophenyl]}fluorenes), NPAPF (9,9-bis[4-(N,N′-bisnaphthalen-2-ylamino)phenyl]-9H-fluorenes), spiro-TAD (2,2′,7,7′-tetrakis(diphenylamino)-9,9′-spirobifluorene), PV-TPD (N,N-di 4-2,2-diphenylethen-1-ylphenyl-N,N-di 4-methylphenylphenylbenzidines), 4P-TPD (4,4′-bis(N,N-diphenylamino)tetraphenyl), or a p-material described in DE102004014046.

In a further embodiment, the n-material system contains fullerenes such as, for example, C₆₀, C₇₀; NTCDA (1,4,5,8-naphthalenetetracarboxylic dianhydrides), NTCDI (naphthalenetetracarboxylic diimides) or PTCDI (perylene-3,4,9,10-bis(dicarboximide)).

In a further embodiment, the p-material system contains a p-dopant, wherein said p-dopant is F4-TCNQ, a p-dopant as described in DE10338406, DE10347856, DE10357044, DE102004010954, DE102006053320, DE102006054524 and DE102008051737, or a transition metal oxide (VO, WO, MoO, etc.).

In a further embodiment, the n-material system contains an n-dopant, wherein said n-dopant is a TTF derivative (tetrathiafulvalene derivative) or DTT derivative (dithienothiophene), an n-dopant as described in DE10338406, DE10347856, DE10357044, DE102004010954, DE102006053320, DE102006054524 and DE102008051737, or Cs, Li or Mg.

In a further embodiment, one electrode is embodied in transparent fashion with a transmission >80% and the other electrode is embodied in reflective fashion with a reflection >50%.

In a further embodiment, the component is embodied in semitransparent fashion with a transmission of 10-80%.

In a further embodiment, the electrodes consist of a metal (e.g. Al, Ag, Au or a combination thereof), a conductive oxide, in particular ITO, ZnO:Al or some other TCO (transparent conductive oxide), a conductive polymer, in particular PEDOT/PSS poly(3,4-ethylenedioxythiophene)poly(styrenesulfonate) or PANI (polyaniline), or of a combination of these materials.

In a further embodiment, the organic materials used have a low melting point, preferably of <100° C.

In a further embodiment, the organic materials used have a low glass transition temperature, preferably of <150° C.

In a further embodiment of the invention, the optical path of the incident light in the active system is enlarged by the use of light traps.

In a further embodiment of the invention, the component is embodied as an organic pin solar cell or organic pin tandem solar cell. In this case, the term tandem solar cell denotes a solar cell which consists of a vertical stack of two solar cells connected in series.

In a further embodiment, the light trap is realized by virtue of the fact that the component is constructed on a periodically microstructured substrate and the homogeneous function of the component, that is to say a short-circuit-free contact-connection and homogeneous distribution of the electric field over the entire area, is ensured by the use of a doped wide-gap layer. Ultrathin components have, on structured substrates, an increased risk of forming local short circuits, with the result that the functionality of the entire component is ultimately jeopardized by such an evident inhomogeneity. This risk of short circuits is reduced by the use of the doped transport layers.

In a further embodiment of the invention, the light trap is realized by virtue of the fact that the component is constructed on a periodically microstructured substrate and the homogeneous function of the component, the short-circuit-free contact-connection thereof and a homogeneous distribution of the electric field over the entire area are ensured by the use of a doped wide-gap layer. In this case, it is particularly advantageous that the light passes through the absorber layer at least twice, which can lead to increased light absorption and thus to an improved efficiency of the solar cell. This can be achieved for example by the substrate having pyramid-like structures on the surface with heights and widths in each case in the range of from one micrometer to hundreds of micrometers. Height and width can be chosen to be identical or different. Likewise, the pyramids can be constructed symmetrically or asymmetrically.

In a further embodiment of the invention, the light trap is realized by virtue of the fact that a doped wide-gap layer has a smooth interface with respect to the i-layer and a rough interface with respect to the reflective contact. The rough interface can be achieved for example by means of a periodic microstructuring. The rough interface is particularly advantageous if it reflects the light diffusely, which leads to a lengthening of the light path within the photoactive layer.

In a further embodiment, the light trap is realized by virtue of the fact that the component is constructed on a periodically microstructured substrate and a doped wide-gap layer has a smooth interface with respect to the i-layer and a rough interface with respect to the reflective contact.

In a further embodiment of the invention, the overall structure of the aptoelectronic component is provided with transparent bottom and top contacts.

In a further embodiment of the invention, the photoactive components according to the invention are used for arrangement on shaped bodies, such as, for instance, glass, concrete, plastics and greenhouses.

For realizing the invention, the above-described embodiments can also be combined with one another.

The invention will be explained thoroughly below on the basis of some exemplary embodiments and figures. In this case, the exemplary embodiments are intended to describe the invention without restricting the latter. In the figures:

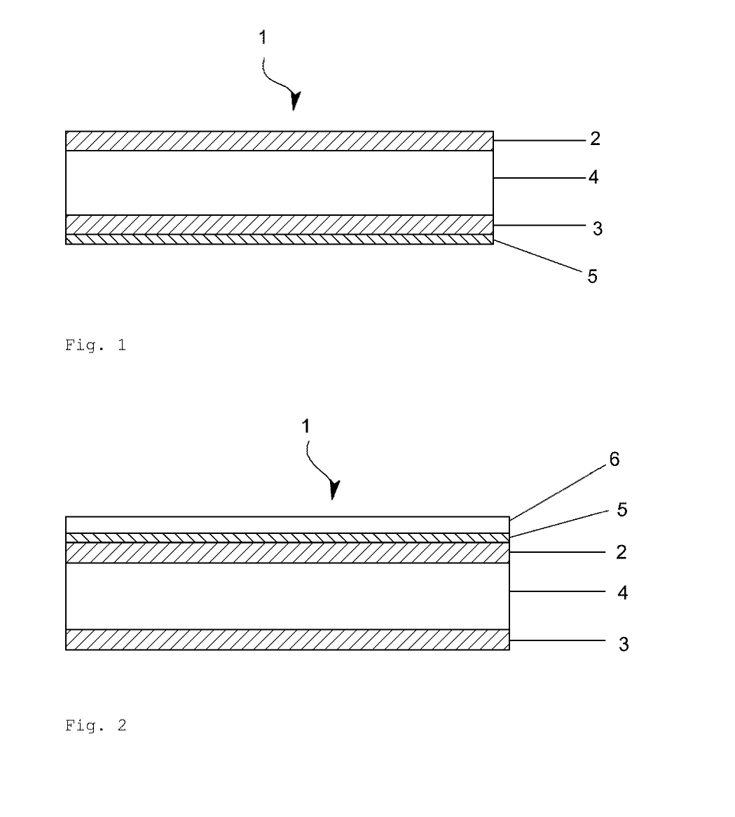

FIG. 1 shows a schematic illustration of a photoactive component according to the invention,

FIG. 2 shows a further schematic illustration of a photoactive component according to the invention,

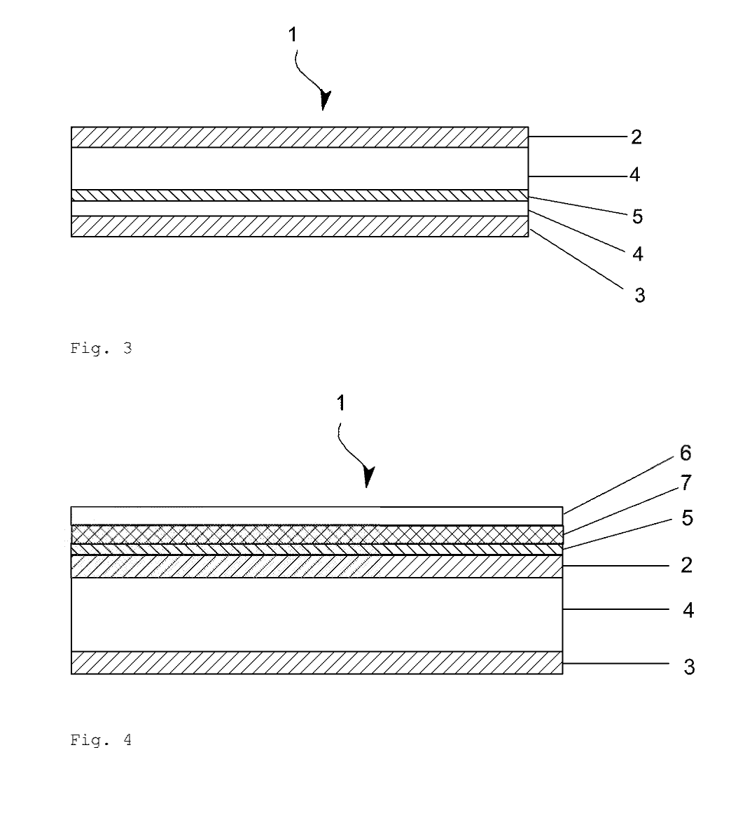

FIG. 3 shows a further schematic illustration of a photoactive component according to the invention,

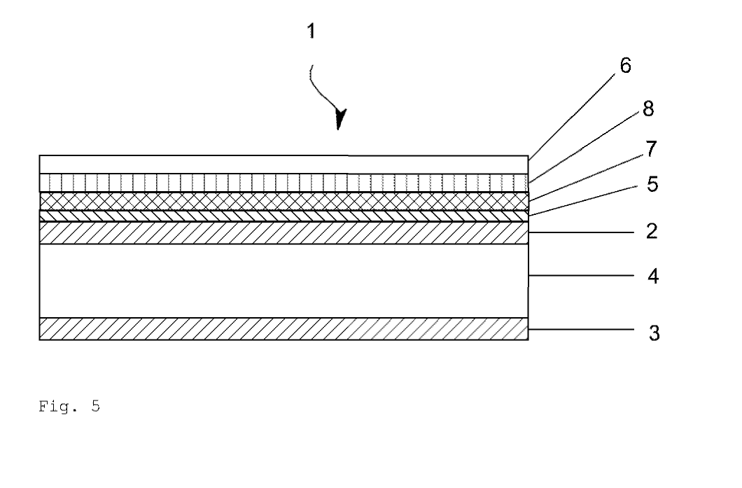

FIG. 4 shows a further schematic illustration of a photoactive component according to the invention with IR filter, and

FIG. 5 shows a further schematic illustration of a photoactive component according to the invention with IR and UV filter.

In a first exemplary embodiment, FIG. 1 illustrates a photoactive component 1 according to the invention, which is embodied for example as an organic solar cell. The latter comprises a first electrode 2, which is embodied for example as a transparent DMD electrode (dielectric-metal-dielectric), and a second electrode 3, which is embodied for example from a transparent conductive oxide, such as ITO, for instance. A photoactive layer system 4 is arranged between these two electrodes 2, 3. Said photoactive layer system 4 can comprise for example a donor-acceptor system composed of small organic molecules. The layer 5 configured as a spectrally selective color filter in at least one range from 450 nm to 800 nm is arranged on the opposite side of the photoactive component 1 relative to the light incidence. Said layer comprises an organic absorbent material, for example. In this case, the substrate (not illustrated in more specific detail) can either be arranged on the light-incident side in the case of the first electrode 2 or be arranged on the opposite side in the case of the second electrode 3.

In a further exemplary embodiment, an alternative configuration of the exemplary embodiment described above is represented in FIG. 2. In this case, the as is the layer 5 configured as a spectrally selective color filter in the range from 450 nm to 800 nm is arranged on the light-incident side. Moreover, the component comprises a coupling-in layer 6, which functions as an antireflection layer or antiscratch protective layer and supports light propagation into the component. In this case, both the layer 5 and the layer 6 can be arranged in an arbitrary order and also in a mixture. In this configuration, too, the substrate (not illustrated in more specific detail) can either be arranged on the light-incident side in the case of the first electrode 2 or be arranged on the opposite side in the case of the second electrode 3.

In a further exemplary embodiment, FIG. 3 illustrates a further component according to the invention. In this case, the layer 5 is embodied as a charge carrier transport layer having absorption in at least one subrange of the wavelength range in the range from 450 nm to 800 nm. In this case, the charge carrier transport layer 5 can be embodied as a hole conductor or electron transport layer, wherein the charge carrier transport layer 5 has absorption which does not contribute to charge carrier generation. In this case, the layer 5 can be embodied for example from MPP or n-C₆₀. By way of example, the charge carrier transport layer can be arranged between two photoactive layer systems 4 of a tandem cell.

In a further exemplary embodiment, an alternative configuration of the exemplary embodiment described above is represented in FIG. 4. In this case, the as is the layer 5 configured as a spectrally selective color filter in the range from 450 nm to 800 nm is arranged on the light-incident side. Moreover, the component comprises a coupling-in layer 6, which functions as an antireflection layer or antiscratch protective layer and supports light propagation into the component. In this case, both the layer 5 and the layer 6 can be arranged in an arbitrary order and also in a mixture. In this configuration, too, the substrate (not illustrated in more specific detail) can either be arranged on the light-incident side in the case of the first electrode 2 or be arranged on the opposite side in the case of the second electrode 3. Furthermore, the photoactive component 1 comprises a layer or layer sequence 7 acting as an IR filter in at least one range from 850 nm to 2500 nm. Heat input into buildings, for example, is reduced as a result.

In a further exemplary embodiment, an alternative configuration of the exemplary embodiment described above is represented in FIG. 5. In this case, the photoactive component 1 comprises a layer or layer sequence 8 acting as a UV filter in at least one range from 250 nm to 430 nm. In this case, the layer functioning as a UV filter serves for protecting the organic molecules contained in the photoactive layer, for example.

### LIST OF REFERENCE SIGNS

1 Photoactive component
2 Electrode
3 Electrode
4 Photoactive layer system
5 Filter layer
6 Coupling-in layer
7 IR filter layer
8 UV filter layer

1. A photoactive component on a substrate comprising a first electrode and a second electrode wherein the first electrode is arranged on the substrate and the second electrode forms a counterelectrode, wherein at least one photoactive layer system is arranged between said first electrode and said second electrode, wherein the photoactive component furthermore comprises at least one layer or layer sequence configured such that said at least one layer or layer sequence acts as a spectrally selective color filter in at least one range from 450 nm to 800 nm in the photoactive component.

2. The photoactive component according to claim 1, further comprising at least one additional layer or layer sequence configured such that the at least one additional layer or layer sequence acts as a spectrally selective IR filter in at least one range from 850 nm to 2500 nm in the photoactive component.

3. The photoactive component according to claim 1, further comprising at least one further layer or layer sequence configured such that the at least one further layer or layer sequence acts as a spectrally selective UV filter in at least one range of the UV range from 250 nm to 430 nm in the photoactive component.

4. The photoactive component according to claim 1, wherein the at least one layer or layer sequence acting as a spectrally selective color filter comprises at least one absorbent material, and wherein the at least one layer or layer system is configured such that it has no electrical contact-connection.

5. The photoactive component according claim 1, wherein the at least one layer or layer sequence is arranged outside the electrodes.

6. The photoactive component according claim 1, wherein the at least one layer or layer sequence comprises organic or inorganic substances or a combination thereof.

7. The photoactive component according to claim 1, wherein the at least one layer or layer sequence comprises nanomaterials embodied as a color-selectively absorbent layer.

8. The photoactive component according to claim 1, wherein the at least one layer or layer sequence comprises at least one fluorescent dye.

9. The photoactive component according to claim 1, wherein the at least one layer or layer sequence is arranged either on a first side of the photoactive component facing light incidence or on a second side of the photoactive component facing away from the light incidence.

10. The photoactive component according to claim 1, wherein the layer or layer sequence on the first side of the photoactive component comprises a metallic structure.

11. The photoactive component according to claim 1, wherein the at least one layer or layer sequence has a layer thickness of at least 3 nm to 100 μm.

12. The photoactive component according to claim 1, wherein the substrate is transparent or opaque.

13. The photoactive component according to claim 1 wherein the substrate comprises glass or film.

14. The photoactive component according to claim 1, wherein the photoactive component comprises an organic solar cell.

15. The photoactive component according to claim 1 in combination with and arranged on a shaped body.

16. The photoactive component according to claim 2, comprising at least one further layer or layer sequence configured such that the at least one further layer or layer sequence acts as a spectrally selective UV filter in at least one range of the UV range from 250 nm to 430 nm in the photoactive component.

17. The photoactive component according to claim 11, wherein the at least one layer or layer sequence has a layer thickness of between 5 mm and 300 mm.
